(19) United States
(12) Patent Application Publication
(10) Pub. No.: US 2014/0021496 A1
(43) Pub. Date: Jan. 23, 2014

(54) THIN FILM TRANSISTOR ARRAY AND EL DISPLAY EMPLOYING THEREOF

(71) Applicant: PANASONIC CORPORATION, Osaka (JP)

(72) Inventors: Hirofumi HIGASHI, Hyogo (JP); Yoshiharu HIDAKA, Hyogo (JP); Nobuto HOSONO, Hyogo (JP)

(73) Assignee: PANASONIC CORPORATION, Osaka (JP)

(21) Appl. No.: 14/032,029

(22) Filed: Sep. 19, 2013

Related U.S. Application Data
(63) Continuation of application No. PCT/JP2012/007518, filed on Nov. 22, 2012.

(30) Foreign Application Priority Data
Jan. 26, 2012 (JP) 2012-013724

(51) Int. Cl. H01L 33/00

(52) U.S. Cl. CPC H01L 33/0041
USPC 257/88

(57) ABSTRACT

An EL display has a luminescence unit having a luminescence layer being disposed between the pair of electrodes, and a transistor array unit controlling the luminescence of the luminescence unit. An interlayer insulating film is disposed between the luminescence unit and the transistor array unit. An electrode of the luminescence unit is connected electrically to the transistor array unit via a contact hole provided in the interlayer insulation film. The transistor array unit has a wiring component made of copper or copper alloy. The wiring component has a lower layer pattern made of copper or copper alloy, and an upper layer pattern made of metal material different from that for the lower layer pattern. The upper layer pattern covers the upper surface and the side surface of the lower layer pattern.

### TECHNICAL FIELD

The present disclosure relates to a TFT (Thin Film Transistor) array having an active layer made of polycrystalline silicon or micro crystallite silicon, and an EL (Electro Luminescent) display employing such a TFT array.

### BACKGROUND

TFTs are employed in driving circuits of display devices such as LCD displays and OLED (Organic Light Emitting Device) displays. TFTs are now further being developed to improve their characteristics. In large-sized displays or high definition displays, these TFTs are required to have high current driving performance. One solution for this requirement is to use a TFT having an active layer made of crystallized semiconductor film such as polycrystalline silicon and micro crystallite silicon.

Instead of a traditional high-temperature process employing temperature of 1000 degrees Celsius or more, a low-temperature process employing temperature of 600 degrees Celsius or less in a heating process has been developed to crystallize the semiconductor films. This low-temperature process can reduce manufacturing cost because it does not require an expensive substrate, e.g. quartz, excellent in heat resistance.

Laser-annealing that uses laser beam in the heating process has been known as one method of low-temperature process. In the laser-annealing, a laser beam is irradiated on a non single crystal semiconductor film, e.g. amorphous silicon or polycrystalline silicon, which is formed on a heat-resistant insulating substrate such as glass. The semiconductor film thus locally heated and melted by this laser radiation is crystallized during a cooling process. TFT is formed integrally using this crystallized semiconductor film as an active layer (channel domain). The crystallized semiconductor film has a high mobility carrier. This improves the performance of the TFT.

The examples of the above discussed TFT are described in Japanese Patent Application Publications JP2001-028486A1 and JP2009-229941A1. They describe bottom-gated structured TFT having gate electrode disposed under semiconductor layer.

In the JP2001-028486A1 describes as follows: a wiring (electrode) connected to a transistor is formed on a substrate, and then a planarized insulation film (interlayer insulation film) made of photosensitive polyimide is formed by spin-coat method so as to cover the wiring. Next, a connection hole (contact hole) is formed on the planarized insulation film using lithography method. An organic EL device, which will be connected to the wiring via the connection hole, is then formed on the planarized insulation film.

JP2009-229941A1 describes a protective insulation film layered on a second metal layer (electrode) and a planarized insulation film (an interlayer insulation film) layered thereon. Both of the insulation films have contact holes to where connecting-contact for electrically connecting the second metal layer and an anode electrode (lower electrode) is inserted in the direction perpendicular to the film surface. The contact hole has a cone-shape tapering downward and the contact hole is formed such that the inner surfaces of the protective insulation film and the planarize insulation film are connected without height difference.

### SUMMARY

The present disclosure relates to an EL display including a luminescence unit employing a luminescence layer disposed between a pair of electrodes, and a TFT (Thin Film Transistor) array unit controlling the luminescence of the luminescence unit. An interlayer insulation film is disposed between the luminescence unit and the TFT array unit, and an electrode of the luminescence unit is connected electrically to the TFT array unit via a contact hole that is provided in the interlayer insulation film. The TFT array unit has a wiring component made of copper or copper alloy. The wiring component comprises a lower layer pattern made of copper or copper alloy, and an upper layer pattern made of a metal material that is different from the lower layer and is formed so as to cover the upper surface and the side surface of the lower layer.

The foregoing structure allows obtaining reliability and low resistance of a wiring component.

### BRIEF DESCRIPTION OF DRAWINGS

FIG. 1 is a perspective diagram of an OLED display according to one embodiment.

FIG. 2 is a perspective diagram illustrating an example of a pixel bank of the OLED display.

FIG. 3 is an electrical circuit diagram illustrating a circuit structure of a pixel circuit.

FIG. 4 is a front view illustrating a structure of a pixel.

FIG. 5 is a sectional view cut along 5-5 line in FIG. 4.

FIG. 6 is a sectional view cut along 6-6 line in FIG. 4.

FIG. 7 is a sectional view illustrating an example of a gate wiring according to one embodiment.

FIG. 8 is a sectional view illustrating an advantage of one embodiment.

### DETAILED DESCRIPTION

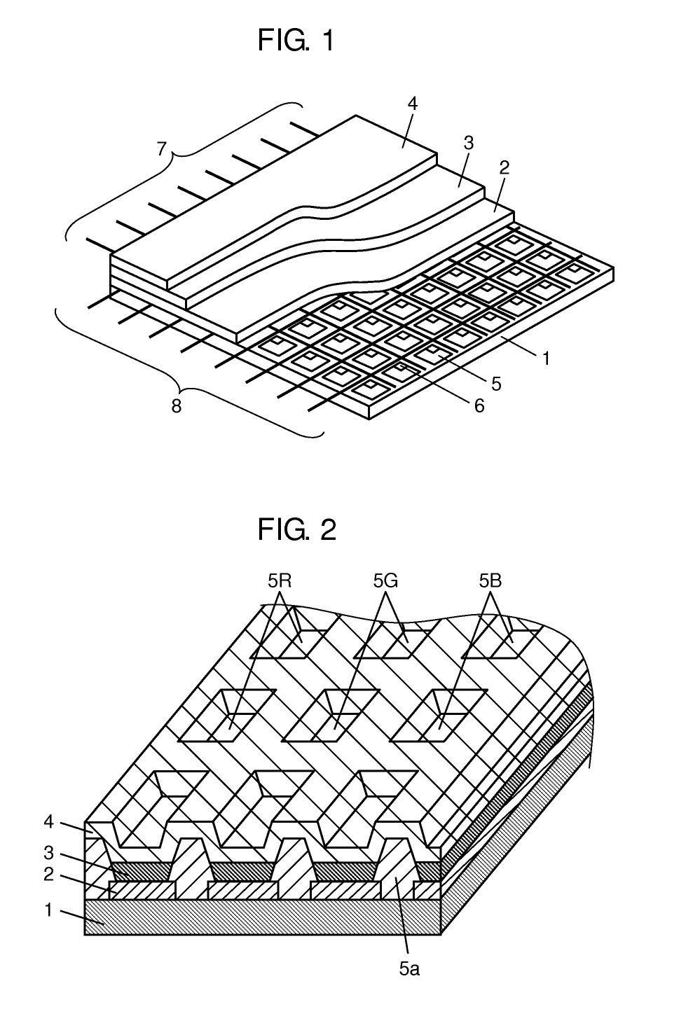

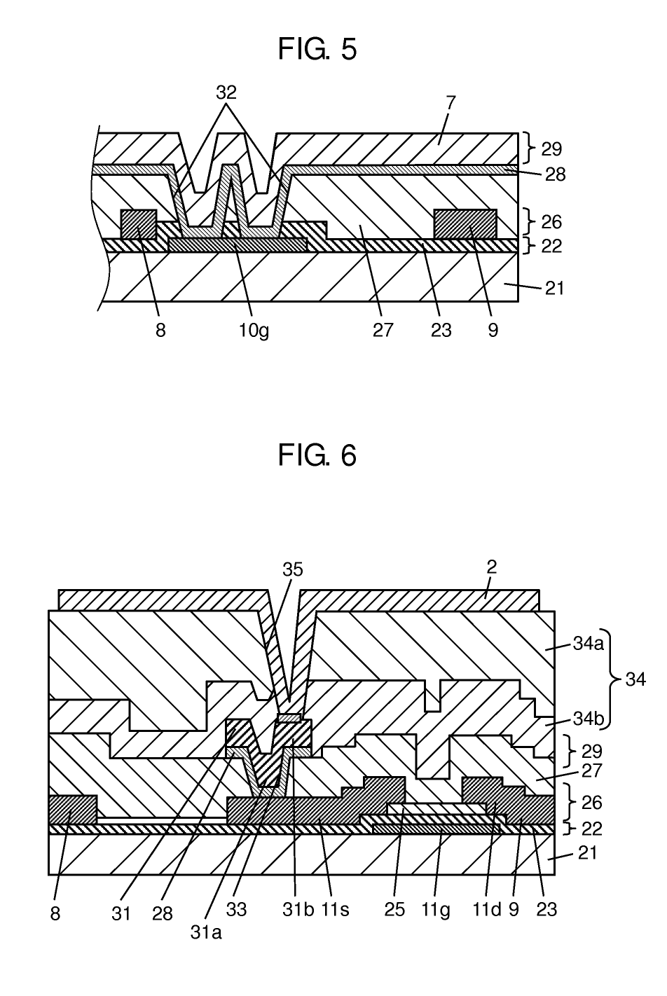

A TFT array unit and an EL display employing the TFT array according to one embodiment is described with reference to FIGS. 1 to 8.

### Structure of EL Display

As illustrated in FIGS. 1 to 3, the EL display comprises: TFT array unit 1; anode 2, EL (Electro Luminescence) layer 3, and cathode 4 (upper electrode) that are layered in this order from the bottom. TFT array unit 1 includes multiple TFTs. Anode 2 is a lower electrode. EL layer 3 is a luminescence layer (or light emitting layer) made of organic material. Cathode 4 is a transparent upper electrode. Anode 2, EL layer 3, and cathode 4 are collectively called “luminescence unit” hereafter. The luminescence unit is controlled by TFT array unit 1.

The luminescence unit has the following structure: EL layer 3 is disposed between a pair of electrodes, i.e. anode 2 and cathode 4; a hole-transport layer is layered between anode 2 and EL layer 3; and an electron-transport layer is layered between EL layer 3 and a transparent cathode 4. TFT array unit 1 has multiple pixels 5 aligned in matrix.

Each of the pixels 5 is controlled by pixel circuit 6 which is provided in each of the pixels 5. TFT array unit 1 has multiple gate wirings 7, source wirings 8, and power supply wirings 9. Gate wirings 7 are aligned in row. Source wirings 8 function as signal lines and are aligned in column such that they intersect with gate wirings 7. As shown in FIG. 4, power supply wirings 9 extend in parallel to source wirings 8.

Each of pixel circuits 6 has TFT 10 working as a switching device and TFT 11 working as a driving device. One gate wiring 7 connects multiple gate electrode 10g of TFTs 10 that are aligned in the same row together. One source wiring 8 connects multiple source electrode 10s of TFTs 10 that are aligned in the same column together. One power supply wiring 9 connects multiple drain electrode 11d of TFTs 11 that are aligned in the same column together.

As illustrated in FIG. 2, each of pixels 5 of the EL display has sub pixels 5R, 5G, and 5B in three colors (red, green, blue) which are formed on a display surface and are aligned in matrix (sub pixels 5R, 5G, 5B are referred to simply as “sub pixels” hereafter). Each of the sub pixels is separated from each other by bank 5a. Bank 5a is formed by a first group of protrusions parallel to gate wirings 7 and a second group of protrusions parallel to source wirings 8 crossing each other. Each of the sub pixels is formed in an area surrounded by these protrusions, i.e. in an opening of bank 5a.

Anodes 2 are formed on an interlayer insulation film of TFT array unit 1 and in the openings of bank 5a for every sub pixels. EL layers 3 are formed separately on anodes 2 for every sub pixels. The transparent cathode 4 is formed continuously so as to cover bank 5a and to commonly cover all of the sub pixels and EL layers 3 of the EL display.

TFT array unit 1 has pixel circuits 6 that are provided for every sub pixels. Each of the sub pixels and each of pixel circuits 6 are connected electrically by a contact hole and a relay electrode.

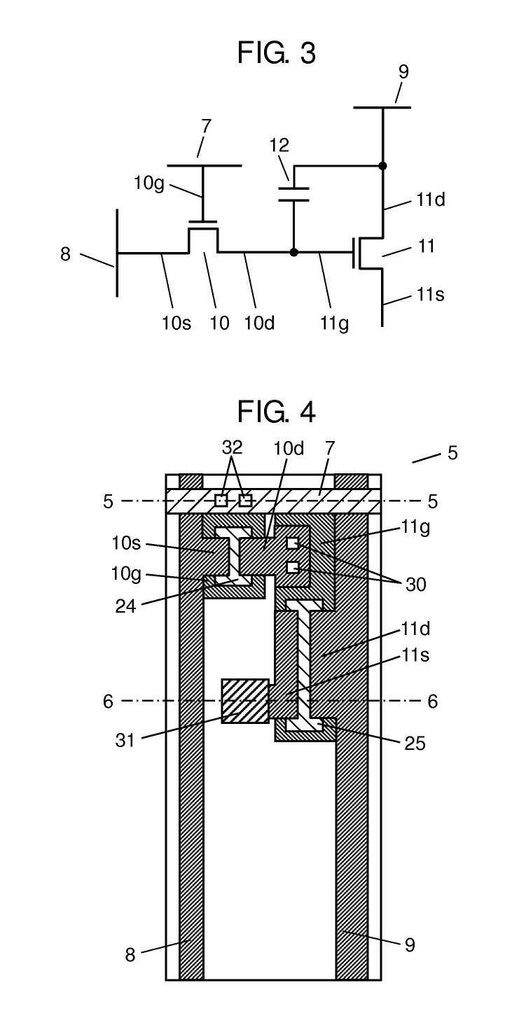

As illustrated in FIG. 3, pixel circuit 6 has TFT 10 working as a switching device, TFT 11 working as a driving device, and capacitor 12 storing data for displaying image.

TFT 10 has gate electrode 10g connected to gate wiring 7; source electrode 10s connected to source wiring 8; drain electrode 10d connected to capacitor 12 and gate electrode 11g of TFT 11; and a semiconductor film. When a voltage is applied to gate wiring 7 and source wiring 8, capacitor 12 is charged with the voltage applied to source wiring 8 as display data.

TFT 11 has gate electrode 11g connected to drain electrode 10d of TFT 10; drain electrode 11d connected to power supply wiring 9 and capacitor 12; source electrode 11s connected to anode 2; and a semiconductor film. TFT 11 supplies a current, having an amount corresponding to the voltage charged in capacitor 12, from power supply wiring 9 to anode 2 via source electrode 11s. In other words, the EL display according to this embodiment employs an active matrix method that controls the display of images for every pixel 5 positioned on the intersections of gate wirings 7 and source wirings 8.

### Structure of Pixel of TFT

Next, a structure of a pixel constituting the TFT array unit is described with reference to FIGS. 4 to 6.

As illustrated in FIGS. 4 to 6, pixel 5 is made of a layered structure comprising: substrate 21; first metal layer 22 which is an electric conduction layer; gate insulation film 23; semiconductor films 24 and 25; second metal layer 26 which is an electric conduction layer; passivation film 27; electric conduction oxide film 28 configured by ITO (Indium Tin Oxide) for example; and third metal layer 29 which is an electric conduction layer.

First metal layer 22 is layered on substrate 21. Gate electrode 10g of TFT 10 and gate electrode 11g of TFT 11 are formed in first metal layer 22. Gate insulation film 23 is formed on substrate 21 and first metal layer 22 such that it covers gate electrodes 10g and 11g.

Semiconductor film 24 is disposed on gate insulation film 23 (between the film 23 and second metal layer 26) and on an area that overlaps with gate electrode 10g. Similarly, semiconductor film 25 is disposed on gate insulation film 23 (between gate insulation film 23 and second metal layer 26) and on an area that overlaps with gate electrode 11g.

Second metal layer 26 is formed on the films 23, 24 and 25. Source wiring 8, power supply wiring 9, and electrodes of TFT 10 (source electrode 10s, drain electrode 10d), and electrodes of TFT 11 (source electrode 11s, and drain electrode 11d) are formed in second metal layer 26.

The electrodes 10s and 10d are formed such that each of them overlaps with a portion of semiconductor film 24 and at this portion these electrodes face each other. Source electrode 10s extends from source wiring 8 that is formed on second metal layer 26.

Similarly, the electrodes 11d and 11s are formed such that each of them overlaps with a portion of semiconductor film 25 and at this portion these electrodes face each other. Drain electrode 11d extends from power supply wiring 9 that is formed on second metal layer 26.

As described above, TFTs 10 and 11 have their gate electrodes 10g and 11g formed on a layer lower than source electrode 10s (11s) and drain electrode 10d (11d). Therefore, TFTs 10 and 11 are called “bottom gate type transistor”.

Gate insulation film 23 has a contact hole 30 that penetrates the film 23 in a thickness direction and at this portion the film 23 overlaps with drain electrode 10d and gate electrode 11g. Drain electrode 10d is connected electrically to gate electrode 11g, which is formed on first metal layer 22, via the contact hole 30.

Passivation film 27 is formed on gate insulation film 23 and second metal layer 26 such that passivation film 27 covers the source electrodes 10s, 11s and drain electrodes 10d, 11d. Passivation film 27 is formed between interlayer insulation film 34 and TFTs 10, 11.

Electric conduction oxide film 28 is layered on passivation film 27. Third metal layer 29 is layered on electric conduction oxide film 28. Gate wiring 7 and relay electrode 31 are formed in third metal layer 29. Electric conduction oxide film 28 is formed selectively on an area overlapping with gate wiring 7 and relay electrode 31. The area overlapping with gate wiring 7 and the area overlapping with relay electrode 31 are not electrically connected.

Gate insulation film 23 and passivation film 27 have a contact hole 32 that penetrates the films in a thickness direction and films 23 and 27 overlap with gate wiring 7 and gate electrode 10g at contact hole 32. Gate wiring 7 is connected electrically to gate electrode 10g formed in first metal layer 22, via the contact hole 32. Gate wiring 7 and gate electrode 10g are not contacted directly with each other because electric conduction oxide film 28 is disposed between them.

Similarly, passivation film 27 has a contact hole 33 that penetrates the film 27 in a thickness direction and at this portion the film 27 overlaps with source electrode 11s of TFT 11 and relay electrode 31. Relay electrode 31 is connected electrically to source electrode 11s, which is formed on second metal layer 26, via the contact hole 33. Source electrode 11s and relay electrode 31 do not directly contact each other because electric conduction oxide film 28 is intervened between them.

Interlayer insulation film 34 is formed on passivation film 27 and third metal layer 29 such that the film 34 covers gate wiring 7 and relay electrode 31. The film 34 has a layered structure and comprises interlayer insulation film 34a working as a planarization film, and interlayer insulation film 34b working as a passivation film. The film 34a is made of organic material film or hybrid film and is formed on the upper side layer that contacts the anode 2. The film 34b is made of inorganic film and is formed on the lower side layer that contacts gate wiring 7 and relay electrode 31.

Bank 5a is formed on interlayer insulation film 34 in at a border with neighboring pixel 5. In the opening of bank 5a, anode 2 and EL layer 3 are formed. One anode 2 is formed for one pixel 5. One EL layer 3 is formed for one color (one sub pixel column) or for one sub pixel. Transparent cathode 4 is formed on EL layers 3 and banks 5a.

As illustrated in FIG. 6, interlayer insulation film 34 has a contact hole 35 that penetrates the film 34 and at this portion the film 34 overlaps with anode 2 and relay electrode 31. Anode 2 is connected electrically to relay electrode 31 formed in third metal layer 29, via the contact hole 35. Relay electrode 31 has central area 31a which will be filled by contact hole 33, and flat area 31b extending in the upper portion of contact hole 33. Anode 2 is connected electrically on flat area 31b of relay electrode 31.

The wiring components, i.e. gate wiring 7 and source wiring 8, are configured by layered structure of a lower layer pattern and an upper layer pattern. The lower layer pattern is made of copper or copper alloy. The upper layer pattern covers the lower layer pattern and is made of metal material that is different from the conductive material of the lower layer pattern.

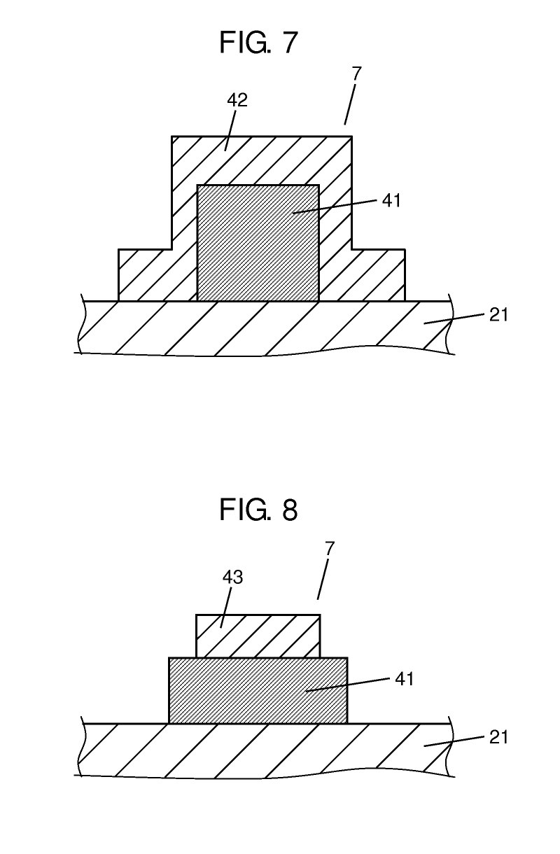

FIG. 7 is a sectional view illustrating an example of gate wiring according to one embodiment, and illustrates a sectional surface which is perpendicular to the extending direction of the wiring. As illustrated in FIG. 7, gate wiring 7 is configured by lower layer pattern 41 and upper layer pattern 42. Lower layer pattern 41 is formed on substrate 21 and is made of copper or copper alloy having a shape of predetermined pattern. Upper layer pattern 42 is also formed on substrate 21 and covers the upper surface and side surface of lower layer pattern 41. Upper layer pattern 42 can be made of molybdenum, or of molybdenum alloy consisting of molybdenum and at least one of metal materials selected from tungsten, neodymium, and niobium.

Recently, due to large sizing of display apparatus, copper or copper alloy has been used for forming wiring components to lower the resistance of the wiring. However, the copper or copper alloy can be oxidized easily. To overcome this problem, the following idea has been proposed: Form a layer made of molybdenum or molybdenum alloy on a wiring component made of copper (or copper alloy), and then fabricate a predetermined circuit pattern using photo-etching.

However, the inventor found out that this forming method has a drawback that the width of the upper layer pattern may become unintentionally smaller than that of the lower layer pattern because the upper layer made of molybdenum or molybdenum alloy may be etched excessively. This may cause an oxidization of the copper or copper alloy of the lower layer or degradation of adhesion to the substrate. FIG. 8 is a sectional view illustrating the upper layer pattern made of molybdenum or a molybdenum alloy being thinned due to an excessive etching of the upper layer pattern. Upper layer pattern 43 of FIG. 8 describes the layer excessively etched.

Gate wiring 7 of this embodiment is made of lower layer pattern 41 and upper layer pattern 42. Lower layer pattern 41 is formed on substrate 21 and is made of copper or copper alloy having a predetermined shape. Upper layer pattern 42 is formed on substrate 21 and covers an upper surface and a side surface of lower layer pattern 41. Upper layer pattern 42 is made of molybdenum or molybdenum alloy, which is different from the material configuring lower layer pattern 41, i.e. copper or copper alloy.

### Manufacturing Method of TFT

The manufacturing method in accordance with this embodiment is demonstrated hereinafter.

First, lower layer pattern 41 made of copper or copper alloy is fabricated by the following steps:

(1) Form a vapor deposition film made of copper or copper alloy having thickness ranging from several tens Å to several thousands Å on substrate 21;

(2) Then form a mask having a predetermined pattern on the vapor deposition film of step (1), and

(3) Remove the vapor deposition film of step (1), except for an area covered by the mask of step (2), using etching process.

Next, upper layer pattern 42 covering lower layer pattern 41 is fabricated by the following steps:

(4) Remove the mask formed in step (2);

(5) Form a vapor deposition film made of molybdenum or molybdenum alloy having thickness ranging from several tens Å to several thousands Å such that they cover the upper surface and the side surface of lower layer pattern 41;

(6) Form a mask having a shape substantially same with the mask of step (2) but having a wider width than the mask of step (2) on the vapor deposition film of step (5),

(7) Remove the vapor deposition film of step (5), except for an area covered by the mask formed in step (6), by using etching process.

The wiring component is thus fabricated by layering lower layer pattern 41 made of copper or a copper alloy, and upper layer pattern 42 covering the pattern 41, where the patter 42 is made of molybdenum or molybdenum alloy formed on substrate 21.

According to the wiring structure of this embodiment, lower layer pattern 41 made of copper or copper alloy and upper layer pattern 42 formed on lower layer pattern 41 are not exposed to a chemical solution at the same time during the etching process. As a result, upper layer pattern 42 is prevented from being formed thinner due to difference between the etching rates of the metals of different kinds or a galvanic corrosion between the different metals. Thus, the oxidization of copper or copper alloy of lower layer pattern 41, or the deterioration of adhesion of the pattern 41 to substrate 21 are prevented.

As discussed above, the gate wiring has been taken as an example; however, the technology of the present disclosure can be applied also to the other wiring components. The above embodiment is an example of two-layered structure having the lower layer pattern made of copper or copper alloy and the upper layer pattern made of molybdenum or molybdenum alloy. However, an intermediate layer can be further formed between the upper and lower layer patterns. This intermediate layer can be made of metal material such as molybdenum, a molybdenum alloy, or other metals, which are the material different from the materials for the upper layer pattern.

In the above embodiment, the number of the TFTs constituting pixel 5 is two. However three TFTs can be employed to compensate the dispersion between the individual TFTs of pixel 5. Even in such case, similar structure to the foregoing structure can be employed. The above embodiment describes a pixel structure for driving an organic EL device; however, the present disclosure can be applied to other types of TFT arrays that are used for LCD displays or inorganic EL displays.

According to the wiring structure of this embodiment, lower layer pattern 41 made of copper or copper alloy and upper layer pattern 42 formed on lower layer pattern 41 are not exposed to a chemical solution at the same time during the etching process. As a result, upper layer pattern 42 is prevented from being formed thinner due to difference between the etching rates of the metals of different kinds or a galvanic corrosion between the different metals. Thus, the oxidization of copper or copper alloy of lower layer pattern 41, or the deterioration of adhesion of the pattern 41 to substrate 21 are prevented.

### INDUSTRIAL APPLICABILITY

The present disclosure is useful for obtaining a reliability and low resistance of the wiring component in a TFT array unit and EL displays employing thereof.

1. An EL display including a luminescence unit having a luminescence layer being disposed between a pair of electrodes, and a thin film transistor (TFT) array unit controlling luminescence of the luminescence unit, wherein an interlayer insulation film is disposed between the luminescence unit and the TFT array unit and an electrode of the luminescence unit is electrically connected with the TFT array unit via a contact hole of the interlayer insulation film,
wherein the TFT array unit has a wiring component made of copper or copper alloy, and
the wiring component includes a lower layer pattern made of copper or copper alloy, and an upper layer pattern made of a metal material different from that for the lower layer pattern and covering an upper surface and a side surface of the lower layer pattern.

2. The EL display of claim 1, wherein
the upper layer pattern is made of molybdenum or molybdenum alloy.

3. A thin film transistor array unit including a current supplying electrode to which an electrode of a luminescence unit is connected via a contact hole formed in an interlayer insulation film disposed between the luminescence unit,
wherein the transistor array unit comprises a wiring component made of copper or copper alloy, and a wiring component comprises a lower layer pattern made of copper or a copper alloy, and an upper layer pattern made of metal material different from that for the lower layer pattern and covers an upper surface and a side surface of the lower layer pattern.

4. The unit of claim 3, wherein
the upper layer pattern is made of molybdenum or molybdenum alloy.
